(19) United States
(12) Patent Application Publication
(10) Pub. No.: US 2012/0301674 A1
(43) Pub. Date: Nov. 29, 2012

(54) METHOD FOR ORGANIZING A BLOCK COPOLYMER

(76) Inventors: Jillian Buriak, Edmonton (CA); Xiaojiang Zhang, Edmonton (CA); Kenneth Harris, Edmonton (CA)

(21) Appl. No.: 13/577,063

(22) PCT Filed: Feb. 7, 2011
(86) PCT No.: PCT/CA11/00140

§ 371 Date: Aug. 3, 2012

Related U.S. Application Data
(60) Provisional application No. 61/301,656, filed on Feb. 5, 2010.

(51) Int. Cl. B05D 5/00; H01L 21/3105; B05D 3/06

(52) U.S. Cl. 428/141; 427/256; 427/532; 427/559; 438/781; 257/E21.242

(57) ABSTRACT

The present disclosure includes a method for organizing a block copolymer (BCP) comprising contacting a substrate with the block copolymer, and exposing the BCP-coated substrate to a suitable energy source under conditions sufficient to induce substrate heating and organize the block copolymer.

### RELATED APPLICATIONS

This is a Patent Cooperation Treaty Application which claims the benefit of 35 U.S.C. 119 based on the priority of corresponding U.S. Provisional Patent Application No. 61/301,656, filed Feb. 5, 2010, which is incorporated herein in its entirety by reference.

### FIELD OF THE DISCLOSURE

The present disclosure relates to a method for organizing a block copolymer by exposing the block copolymer to energy which results in the heating of the substrate.

### BACKGROUND OF THE DISCLOSURE

Block copolymers (BCPs) organize into nanostructures through phase separation. After phase separation, several methods of transferring the BCP nanopattern into alternate materials are available. For instance, metallic nanostructures can be templated by exposing a BCP film on a surface to an appropriate metal salt. Subsequently, the original BCP polymer is removed leaving a pattern of metal structures on the surface replicating the pattern of the phase-separated BCP features. The feature size and spacing are generally determined by the block lengths within the BCP, and by varying these parameters, different arrangements of nanostructures are formed. Once formed, the BCP patterns may be utilized directly or transferred into other materials by a wide assortment of techniques.

Generally, the organization of BCP nanostructures is improved through one of two processes: thermal annealing or solvent-assisted annealing. Without any annealing, the BCP structures are usually somewhat ordered. Annealing is intended to improve the order of the structures, or change the structures, for example, from dots to lines. In thermal annealing, the BCP film is simply heated above its glass transition temperature on a hotplate or in an oven. This process induces some fluidity in the BCP film and allows the constituent blocks to organize into the thermodynamically preferred, highly ordered state. In solvent-assisted annealing, the BCP film is exposed to an appropriate solvent which interacts with one or both of the BCP blocks. The solvent often reduces the glass transition temperature or provides a chemical driving force for the diffusion and reorganization of the polymer segments into a higher organization state. However, the timescale of the thermal annealing and solvent-assisted annealing processes is generally hours or days.

### SUMMARY OF THE INVENTION

It has now been determined that by exposing a block copolymer to any form of energy which induces substrate heating, the organization of the block copolymer into nanostructures, such as nanodot arrays or parallel nanolines, is accelerated.

Accordingly, in an embodiment of the disclosure, there is included a method for organizing a block copolymer (BCP), comprising:
(i) contacting a substrate with the BCP, wherein the BCP has at least a first block and a second block; and
(ii) exposing the BCP-coated substrate to a suitable energy source under conditions sufficient to induce substrate heating and arrange at least the first and second blocks into organized domains.

In another embodiment, the suitable energy source is an electromagnetic energy source, an electrical energy source, or a magnetic energy source. In another embodiment, the electromagnetic energy source provides electromagnetic energy to induce substrate heating and the electromagnetic energy comprises microwave radiation energy or infrared energy. In another embodiment, the electrical energy source provides an electrical current to induce substrate heating and the electrical current is passed through electrically-conductive materials in contact with the substrate. In another embodiment, the electrical energy source provides an electrical current to induce substrate heating, and the electrical current is passed directly through the substrate. In another embodiment, the magnetic energy source provides magnetic energy to induce substrate heating, and the magnetic energy source comprises magnetic fields.

In another embodiment, the BCP-coated substrate is exposed to a suitable energy source while in the presence of a solvent or solvent vapour.

In another embodiment, the domains of the block copolymer are organized into nanostructures, such as nanodot arrays or parallel nanolines.

In a further embodiment, the organized domains of the block copolymer have a length and the length determines the size of the nanostructures. In another embodiment, the nanostructures comprise parallel cylinders, optionally oriented along the substrate or perpendicular to the substrate. In another embodiment, the nanostructures form a nanodot array, such as a hexagonal nanodot array. In another embodiment, the nanostructures form lamellar, or plate-like, structures, optionally oriented parallel to the substrate or perpendicular to the substrate. In another embodiment, the nanostructures form mixed patterns optionally incorporating cylinders and dots, or cylinders and lamellae, or another combination.

In another embodiment of the disclosure, the block copolymer is a diblock copolymer. In a further embodiment, the diblock copolymer is a polymer of the formula (I):

A-B (I)

wherein A is a repeating polymeric monomer unit of the formula (II):

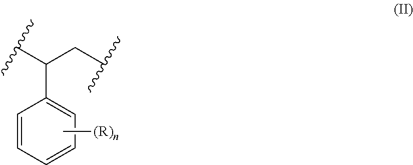

wherein each R is independently or simultaneously selected from H, halo, (C₁-C₆)-alkyl, —O—(C₁-C₆)-alkyl or fluoro-substituted-(C₁-C₆)-alkyl, and

n is 1, 2, 3, 4 or 5; and
B is a repeating polymeric monomer unit of the formula (III):

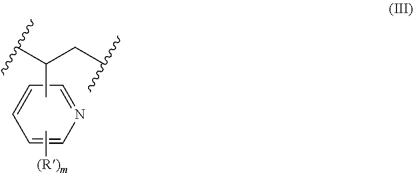

wherein each R′ is independently or simultaneously selected from H, halo, (C₁-C₆)-alkyl, —O—(C₁-C₆)-alkyl or fluoro-substituted-(C₁-C₆)-alkyl, and
m is 1, 2, 3 or 4.

In another embodiment, A is

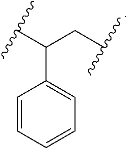

In another embodiment, B is

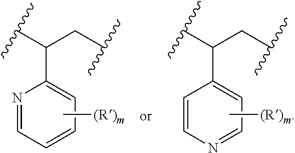

wherein each R′ is independently or simultaneously selected from H, halo, (C₁-C₆)-alkyl, —O—(C₁-C₆)-alkyl or fluoro-substituted-(C₁-C₆)-alkyl, and

m is 1, 2, 3 or 4.

In an embodiment, B is

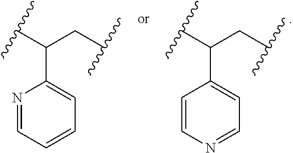

In another embodiment of the disclosure, the substrate comprises semiconductors such as (but not limited to) silicon (Si), gallium arsenide (GaAs), and germanium (Ge); doped semiconductors; metals; plastic films; glasses; ceramics; transparent conducting oxides such as (but not limited to) indium tin oxide; or topographically-patterned or chemically-patterned versions of these substrates.

In another embodiment, the block copolymer is contacted with the substrate in the presence of a solvent. In another embodiment of the disclosure, the solvent is toluene.

In another embodiment, the BCP-coated substrate is exposed to an energy source, for example, microwave radiation, infrared radiation, electrical current, or magnetic fields, for between 1 second and 24 hours, optionally between 1 second and 5 minutes, optionally between 1 second and 4 minutes. In another embodiment, the BCP-coated substrate is exposed to an energy source for less than 4 minutes, optionally less than 90 seconds. In one embodiment, the energy source comprises microwave radiation.

In another embodiment, when the energy source is microwave radiation from a microwave source, the microwave radiation has a frequency of between 400 MHz and 25 GHz. In a further embodiment, the microwave radiation has a power density of between 5 mW/cm³ and 800 W/cm³.

The present disclosure is also directed to a substrate comprising nanostructures produced in accordance with the method of the present disclosure.

Other features and advantages of the present disclosure will become apparent from the following detailed description. It should be understood, however, that the detailed description and the specific examples while indicating preferred embodiments of the disclosure are given by way of illustration only, since various changes and modifications within the spirit and scope of the disclosure will become apparent to those skilled in the art from this detailed description.

### BRIEF DESCRIPTION OF THE DRAWINGS

The present disclosure will now be described in greater detail with reference to the attached drawings in which:

FIG. 1 shows a micrograph of organized metallic nanolines templated using block copolymers of the present disclosure;

FIG. 2 shows micrographs of metallized patterns templated using block copolymers of the present disclosure organized at different temperatures using microwave radiation in the presence of toluene;

FIG. 3 shows micrographs of metallized patterns templated using block copolymers of the present disclosure organized at different temperatures using microwave radiation in the presence of tetrahydrofuran;

FIG. 4 shows micrographs of metallized patterns templated using block copolymers of the present disclosure on various substrates having different resistivities;

FIG. 5 shows micrographs of domains of organized metallic nanolines templated by varying block lengths of block copolymers of the present disclosure;

FIG. 6 shows a micrograph of PS-PMMA micelles in an aspect of the disclosure domains organized using microwave radiation in an aspect of the disclosure;

FIG. 7 shows a micrograph of a pattern of platinum lines on a silicon substrate pre-patterned with a silica guide;

FIG. 8 shows a micrograph of a metallic pattern templated by block copolymers that were organized using radiation from a conventional microwave oven in an aspect of the disclosure; and

FIG. 9 shows a micrograph of organized metallic nanolines templated by block copolymers that were organized using radiation from a conventional microwave oven in an aspect of the disclsoure.

### DETAILED DESCRIPTION OF THE DISCLOSURE

### (I) Definitions

The term “(C₁-C₆)-alkyl” as used herein means straight and/or branched chain, saturated alkyl radicals containing from one to six carbon atoms and includes methyl, ethyl, n-propyl, isopropyl, n-butyl, s-butyl, isobutyl, t-butyl, 2,2-dimethylbutyl, n-pentyl, 2-methylpentyl, 3-methylpentyl, 4-methylpentyl, n-hexyl and the like.

The term “fluoro-substituted” as used herein refers to an alkyl group in which at least one, up to and including all, of the hydrogen atoms bonded to the alkyl group are replaced by fluorine atoms.

The term “(C₁-C₆)-alkoxy” as used herein means straight and/or branched chain, saturated alkoxy radicals containing from one to six carbon atoms and includes methoxy, ethoxy, n-propoxy, isopropoxy, n-butoxy, s-butoxy, isobutoxy, t-butoxy, 2,2-dimethylbutoxy, n-pentoxy, 2-methylpentoxy, 3-methylpentoxy, 4-methylpentoxy, n-hexoxy and the like.

The term “halo” us used herein means any of the halogen atoms fluorine, chlorine, bromine and iodine.

The term “substrate” as used herein refers to any substrate in which the surface can be coated with a block copolymer. Examples of substrates include, but are not limited to, semiconductors such as (but not limited to) silicon, GaAs, and Ge; doped semiconductors, metals including (but not limited to) aluminum, gold, silver, and copper; plastic films such as (but not limited to) polyethylene terephthalate; and any of these preceding substrates coated with transparent conducting oxides such as (but not limited to) indium tin oxide.

The term “non-substrate energy absorber” refers to thin films or other materials placed in contact with or near the substrate and which are intended to absorb energy radiation. Energy absorption by the non-substrate energy absorber supplements or replaces energy absorption by the substrate.

The term “contacting” as used herein refers to the intimate contact of a particular reagent with a specific substrate. In an embodiment, the term contacting refers to the intimate contact of a block copolymer with the surface of the substrate such that a film of block copolymer is applied to the substrate. In an embodiment, the block copolymer is applied as a neat solution, or is applied with a solvent, such as toluene.

The term “organized” or “organizing” as used herein refers to the arrangement of the blocks of a block copolymer and their ability to arrange into thermodynamically favourable positions or conformations as a result of hydrophobic and hydrophilic or other molecular interactions in the polymer blocks (e.g., hydrophobic components will organize together and hydrophilic components will organize together to form specific nanostructures which will be dependent upon the identity of the blocks in the block copolymer). In an embodiment, the organization of the block copolymers is accelerated using microwave radiation, infrared radiation, electrical energy or magnetic energy.

The term “suitable energy source” as used herein refers both to (i) any form of energy such as microwave radiation, infrared radiation, magnetic fields, electrical energy or any other form of radiation, and (ii) to the sources/devices which produce or provide such energy, such as a microwave oven to produce microwave radiation, electrical current to provide electrical energy, infrared light to provide infrared radiation and inductive heaters to provide magnetic energy. Any of the above energy sources will be sufficient to induce heating in the substrate.

The phrase “conditions sufficient to induce substrate heating” as used herein refers to the ability of the energy source to heat the substrate to a temperature which results in the domains of the block copolymer organizing into thermodynamically favourable positions and forming nanostructures, such as nanodot arrays or nanolines, on the substrate. For example, when the energy source is a microwave oven or microwave radiation, the microwave radiation induces heating in the substrate which subsequently heats the block copolymers and results in the domains of the block copolymer organizing into thermodynamically favourable positions.

The term “nanostructures” as used herein includes nanoscale features or shapes, such as, but not limited to, micelles, cylinders, nanowires, nanolines, nanorods, and lamellae. Nanostructures may comprise various materials, including block copolymers, metals, and metal oxides. Examples of nanostructures include, but are not limited to, block copolymer domains, metal nanoparticles, and metal nanolines (or metal cylinders). Nanostructures may be arranged in a disordered fashion or may be arrayed in an orderly fashion.

The term “copolymer” as used herein refers to a polymer comprising two or more chemically-distinct monomeric subunits. These monomeric subunits are covalently attached to one another in a single polymer chain.

The term “block copolymer” as used herein refers to a copolymer comprising two or more monomeric subunits, wherein the monomeric subunits are grouped into blocks containing only one type of monomeric subunit. These blocks are covalently attached to other blocks containing different subunits in the same polymer chain, and the monomeric subunits of the block copolymer undergo phase segregated arrangement as a result of the affinity of the monomeric subunits to organize with similar monomeric subunits.

The term “blocks” as used herein refers to portions of a block copolymer, comprised of repeating units of the same monomeric subunits. These blocks are covalently attached to other blocks containing different subunits in the same polymer chain, and the monomeric subunits of the block copolymer undergo phase-segregated arrangement as a result of the affinity of the monomeric subunits to organize with similar monomeric subunits. For example, in a block copolymer, such as PS-b-P2VP, polystyrene comprises one block, while poly-2-vinylpyridine comprises the other block.

The term “domain” as used herein refers to a specific accumulation of a particular polymer block over an area of the substrate. In an embodiment, the arrangement of domains comprises specific nanostructures, such as nanodots or nanolines. In an embodiment, a collection of a particular block of a block copolymer comprises a domain, and these domains organize into, for example, nanodots or nanolines, as a result of hydrophobic and hydrophilic interactions in the polymer domains (“like” blocks will organize together to form domains).

The term “diblock copolymer” as used herein refers to a block copolymer in which there are only two blocks of monomeric subunits.

The term “metal salt” as used herein refers to any metallic salt in which the metal ions are able to diffuse through a block copolymer and bind to the block copolymer domains. Examples of metal salts include, but are not limited to, CoCl₂, ZnCl₂, Na₂PtCl₄, Na₂PdCl₄ or HAuCl₄. It will be understood that when the term metal salt is used in the context of a first and/or second metal salt, the BCP-coated substrate is first contacted with a first metal salt, and subsequently, contacted with a second metal salt. A BCP-coated substrate may also be contacted with two or more metal salts simultaneously.

The term “metal ion” as used herein refers to the charged metal atom of the metal salt. Accordingly, examples of metal ions include, but are not limited to, Co²⁺, Zn²⁺, PtCl₄²⁻, PdCl₄²⁻ or AuCl₄⁻.

### (II) Method of the Disclosure

It has now been determined that by exposing a block copolymer to any form of energy or energy source which induces substrate heating, the organization of the block copolymer into nanostructures, such as nanodot arrays or nanolines, is accelerated.

Accordingly, in an embodiment of the disclosure, there is included a method for organizing a block copolymer (BCP), comprising:
(i) contacting a substrate with the BCP, wherein the BCP has at least a first block and a second block; and
(ii) exposing the BCP-coated substrate to a suitable energy source under conditions sufficient to induce substrate heating and arrange at least the first and second blocks into organized domains.

In another embodiment, the suitable energy source is an electromagnetic energy source, an electrical energy source, or a magnetic energy source. In another embodiment, the electromagnetic energy source provides electromagnetic energy to induce substrate heating and the electromagnetic energy comprises microwave radiation energy or infrared energy. In another embodiment, the electrical energy source provides an electrical current to induce substrate heating, and the electrical current is passed through electrically-conductive materials in contact with the substrate. In another embodiment, the electrical energy source provides an electrical current to induce substrate heating, and the electrical current is passed directly through the substrate. In another embodiment, the magnetic energy source provides magnetic energy to induce substrate heating, and the magnetic energy source comprises magnetic fields.

In an embodiment, the source of microwave radiation comprises a magnetron, a klystron, a gyrotron or travelling wave tube. In another embodiment, the source of microwave radiation comprises a magnetron. In another embodiment, the BCP-coated substrate is irradiated with microwaves generated by the magnetron.

In another embodiment, a non-substrate energy absorber is placed in close proximity to the BCP-coated substrate. The non-substrate energy absorber supplements or replaces energy absorption by the substrate and induces substrate heating and provides additional heat to the BCP film. In another embodiment, the non-substrate energy absorber is in direct contact with the substrate, optionally underneath the substrate.

In another embodiment, the BCP-coated substrate or non-substrate energy absorber is irradiated with microwave radiation comprising a frequency of between 400 MHz and 25 GHz, optionally between 1 GHz and 5 GHz, optionally between 2 GHz and 3 GHz. In another embodiment, the BCP-coated substrate or non-substrate energy absorber is irradiated with microwave radiation comprising a frequency of 2.45 GHz. In another embodiment of the disclosure, the BCP-coated substrate is irradiated with microwave radiation in a volume of space comprising a power density between 50 mW/cm³ and 800 W/cm³, optionally between 50 mW/cm³ and 200 W/cm³, optionally between 100 mW/cm³ and 200 W/cm³, optionally between 200 mW/cm³ and 50 W/cm³, optionally between 500 mW/cm³ and 50 W/cm³, optionally between 1 W/cm³ and 50 W/cm³. The lower the power of the radiation, the longer the BCP-coated substrate will need to be exposed to microwave radiation. In another embodiment, the BCP-coated substrate or non-substrate energy absorber is irradiated with microwave radiation comprising a power density of 10 W/cm³.

In another embodiment of the disclosure, the BCP-coated substrate or non-substrate energy absorber is irradiated with microwave radiation for a time between 1 second and 24 hours, optionally between 10 seconds and 20 minutes, optionally between 30 seconds and 20 minutes, optionally between 1 minute and 20 minutes, optionally between 2 minutes and 10 minutes, optionally between 3 minutes and 7 minutes, optionally 3 minutes to 5 minutes. In another embodiment, the BCP-coated substrate is irradiated with microwave radiation for 4 minutes, optionally less than 4 minutes.

In an embodiment of the disclosure, the substrate or non-substrate energy absorber absorbs the microwave energy during the irradiation, and subsequently, the temperature of the substrate increases, which then heats the block copolymer. In an embodiment, the temperature increases to a temperature between 50° C. and 500° C., optionally between 70° C. and 400° C., 100° C. and 300° C., 100° C. and 200° C., optionally 150° C.

In another embodiment, the BCP-coated substrate is exposed to microwave energy while in the presence of a solvent and/or solvent vapour. In an embodiment, the solvent is a microwave absorber such as, but not limited to, tetrahydrofuran. The solvent absorbs microwave energy, heats up and partially vaporizes, increasing the vapor pressure in the vicinity of the BCP film. In an embodiment, this increase in solvent vapour pressure assists in the organization of the block copolymer film.

In another embodiment, the suitable energy source is infrared radiation. In an embodiment, the infrared radiation is generated by an infrared lamp, and conditions sufficient to induce substrate heating are created by the lamp. In another embodiment, the BCP-coated substrate or non-substrate energy absorber is exposed to infrared energy while in the presence of a solvent and/or solvent vapour. In an embodiment, the solvent absorbs infrared energy, heats up and partially vaporizes, increasing the vapour pressure in the vicinity of the BCP film. In an embodiment, this increase in solvent vapour pressure assists in the organization of the block copolymer film.

In another embodiment, the suitable energy source is electrical energy. In an embodiment, the substrate is patterned with metal or other electrically-conductive wires. In an embodiment, electric current is passed through the wires, and electrical energy is transferred to the substrate in the form of resistive heating, creating conditions sufficient to induce substrate heating. In another embodiment, the BCP-coated substrate is exposed to electrical energy while in the presence of a solvent and/or solvent vapour. In an embodiment, the solvent partially vaporizes, increasing the vapour pressure in the vicinity of the BCP film. In an embodiment, this increase in solvent vapour pressure assists in the organization of the block copolymer film.

In another embodiment, the suitable energy source is electrical energy. In an embodiment, an electric field produces an electric current which flows directly into the BCP-coated substrate or a non-substrate energy absorber in contact or near the BCP-coated substrate. The electric current induces resistive heating. In another embodiment, the BCP-coated substrate or non-substrate energy absorber is exposed to electrical energy while in the presence of a solvent and/or solvent vapour. In an embodiment, the solvent partially vaporizes, increasing the vapour pressure in the vicinity of the BCP film. In an embodiment, this increase in solvent vapour pressure assists in the organization of the block copolymer film.

In another embodiment, the suitable energy source is magnetic energy. In an embodiment, the BCP-coated substrate or non-substrate energy absorber absorbs magnetic energy in an inductive process. In an embodiment, the magnetic energy is in the form of magnetic fields that are generated by an inductive heater. In an embodiment, the magnetic fields induce electrical currents in the BCP film and/or substrate and/or energy absorber, and these electrical currents lead to heating of the BCP film and/or substrate and/or energy absorber. In an embodiment, this creates conditions sufficient to induce substrate heating. In another embodiment, the BCP-coated substrate or non-substrate energy absorber is exposed to magnetic energy while in the presence of a solvent and/or solvent vapour. In an embodiment, the solvent partially vaporizes, increasing the vapour pressure in the vicinity of the BCP film. In an embodiment, this increase in solvent vapour pressure assists in the organization of the block copolymer film.

In another embodiment, the thickness of the polymer layer is controlled by the concentration of the block copolymer applied in a coating solution to the substrate. In an embodiment, the block copolymer is dissolved in a suitable organic solvent such as toluene, THF, chlorobenzene, or any other solvent which solubilizes the block copolymer, at a concentration of between 0.1 wt % and 5 wt %, 0.5 wt % and 3 wt %, suitably between 1.5 wt % and 2.5 wt %, optionally 2.0 wt %.

In another embodiment of the disclosure, the block copolymer is spin-coated on the substrate. Accordingly, for example, in an embodiment, a 2.0 wt % solution of the block copolymer in toluene is spin-cast at a speed of between 500 rpm and 7,000 rpm, optionally between 2,000 rpm and 6,000 rpm, optionally between 3,000 rpm and 5,000 rpm, optionally 4,000 rpm, at an acceleration of between 4,000 rpm/s and 10,000 rpm/s, optionally between 5,000 rpm/s and 9,000 rpm/s, 6,000 rpm/s and 8,000 rpm/s, 7,500 rpm/s and 8,000 rpm/s, optionally 7,700 rpm/s. In an embodiment, under the conditions for the phase-segregated arrangement, the thickness of the block copolymer coated on the substrate is between 20 nm and 150 nm, optionally between 40 nm and 120 nm, optionally between 60 nm and 100 nm, optionally between 65 nm and 80 nm, optionally between 65 nm and 70 nm, optionally 70 nm. The speed of spin-coating, the concentration of the BCP in a particular solvent, the power, time and frequency of the energy source and the solvent environment are all interrelated factors which affect the organization of the block copolymer domains.

In another embodiment, the domains of the block copolymer film are organized into a nanodot array or into nanolines.

In a further embodiment, the blocks of the block copolymer have a length and the length determines the size of the nanostructures. In another embodiment, the nanostructures comprise parallel cylinders oriented along the substrate or perpendicular to the substrate. In another embodiment, the nanostructures form a hexagonal nanodot array, in which the array comprises a hexagonal arrangement of nanodots. In an embodiment, the nanostructures have at least one dimension between 1 nm and 500 nm in size, optionally between 5 nm and 300 nm.

In an embodiment, the molecular weight of the first block of the block polymer is between 3,000 and 2,000,000, optionally between 7,000 and 175,000, between optionally 10,000 and 75,000, optionally 23,600 g/mol. In an embodiment, the first block of the block copolymer comprises polystyrene and/or polystyrene derivatives. In another embodiment, the molecular weight of the second block of the block copolymer is between 3,000 and 2,000,000, optionally between 4,000 and 100,000, optionally between 8,000 and 40,000, optionally 10,400 g/mol. In another embodiment, the second block of the block copolymer comprises poly-2-vinylpyridine.

In another embodiment of the disclosure, the block copolymer is a diblock copolymer. In a further embodiment, the diblock copolymer is a polymer of the formula (I):

A-B (I)

wherein A is a repeating polymeric monomer unit of the formula (II):

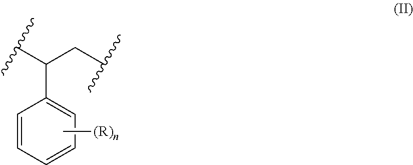

wherein each R is independently or simultaneously selected from H, halo, (C₁-C₆)-alkyl, —O—(C₁-C₆)-alkyl or fluoro-substituted-(C₁-C₆)-alkyl, and
n is 1, 2, 3, 4 or 5; and
B is a repeating polymeric monomer unit of the formula (III):

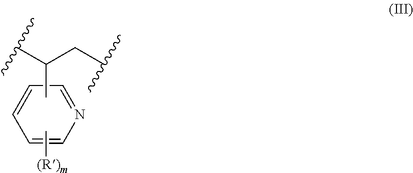

wherein each R′ is independently or simultaneously selected from H, halo, (C₁-C₆)-alkyl, —O—(C₁-C₆)-alkyl or fluoro-substituted-(C₁-C₆)-alkyl,
and
m is 1, 2, 3 or 4.

In another embodiment, A is

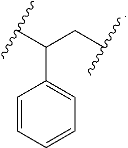

In another embodiment, B is

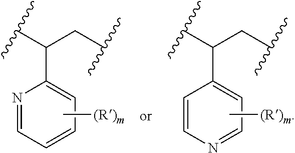

wherein each R′ is independently or simultaneously selected from H, halo, (C₁-C₆)-alkyl, —O—(C₁-C₆)-alkyl or fluoro-substituted-(C₁-C₆)-alkyl,
and
m is 1, 2, 3 or 4.

In an embodiment, B is

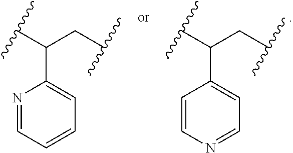

In another embodiment, one block of the diblock copolymer comprises polymethylmethacrylate or polydimethylsiloxane. In another embodiment, one block of the diblock copolymer comprises polymethylmethacrylate.

In another embodiment of the disclosure, the block copolymer comprises polystyrene-block-polyvinylpyridine (PS-b-PVP), polystyrene-block-polyethyleneoxide (PS-b-PEO), polyethyleneoxide-block-polyisoprene (PEO-b-PI), polyethyleneoxide-block-polybutadiene (PEO-b-PBD), polyethyleneoxide-block-polymethylmethacrylate (PEO-b-PM MA), polyethyleneoxide-block-polyvinylpyridine (PEO-b-PVP), polystyrene-block-polymethylmethacrylate (PS-b-PMMA), polyvinylpyridine-block-polymethylmethacrylate (PVP-b-PMMA), polyethyleneoxide-block-polyethylethylene (PEO-b-PEE), polystyrene-block-polybutadiene (PS-b-PBD), polystyrene-block-polydimethylsiloxane (PS-PDMS), styrene-isoprene-styrene (SIS), or polybutadiene-block-polyvinylpyridine (PBD-b-PVP). In another embodiment, the block copolymer comprises polystyrene-block-poly-2-vinyl-pyridine (PS-b-P2VP), polystyrene-block-poly-4-vinyl-pyridine (PS-b-P4VP), polystyrene-block-polymethylmethacrylate (PS-b-PMMA) or polystyrene-block-polydimethylsiloxane (PS-PDMS). In another embodiment, the block copolymer comprises polystyrene-block-poly-2-vinyl-pyridine (PS-b-P2VP), polystyrene-block-poly-4-vinyl-pyridine (PS-b-P4VP), or polystyrene-block-polymethylmethacrylate (PS-b-PMMA). In one embodiment, one block of the diblock copolymer comprises polymethylmethacrylate or polydimethylsiloxane. In another embodiment, the disclosure also comprises exposing a substrate to a suitable energy source comprising any block copolymer films including diblock, triblock and multiblock copolymers or blends of several block copolymers. One skilled in the art will understand that it is possible to synthesize and use a large variety of different block copolymers, and that the substitution of a different block copolymer does not constitute a departure from the disclosure.

In another embodiment of the disclosure, the substrate comprises semiconductors such as silicon, GaAs, and Ge; metals; plastic films; glasses; ceramics; transparent conducting oxides such as (but not limited to) indium tin oxide; or topographically-patterned or chemically-patterned versions of these substrates.

In another embodiment, the block copolymer is contacted with the substrate in the presence of a solvent. In another embodiment of the disclosure, the solvent is an organic solvent such as tetrahydrofuran, toluene or xylene.

In a further embodiment of the disclosure, the block copolymer comprises functional groups that bind to a metal salt. In an embodiment, functional groups comprise any moiety that is able to bind to the metal ion of a metal salt. For example, the functional group comprises a pyridine moiety which is able to bind metal ions.

In an embodiment, the annealed BCP patterns (for examples, the organized nanodot arrays or nanolines) are transferred to the substrate by contacting the organized BCP-coated substrate with a metal salt under conditions for the metal ions to bind to the domains of the block copolymer. In another embodiment, the metal salt is CoCl₂, ZnCl₂, Na₂PtCl₄, Na₂PdCl₄ or HAuCl₄. In another embodiment, the metal ion is Co²⁺, Zn²⁺, PtCl₄²⁻, PdCl₄²⁻ or AuCl₄⁻.

In another embodiment of the disclosure, the method further comprises treating the metal-bound BCP with plasma to reduce the metal and remove the block copolymer from the substrate.

In another embodiment, the method further comprises selectively etching the organized BCP-coated substrate such that the BCP is treated with an etchant that selectively attacks one of the blocks. In an embodiment, the etching removes one block and exposes the substrate underneath only that block. In another embodiment, after this, the exposed areas are attacked with a different chemical.

In another embodiment of the disclosure, the organized BCP film is selectively etched by ozone treatment or reactive ion etching. In another embodiment, the BCP is PS-b-PBD, the substrate is silicon nitride, and following exposure to a suitable energy source, the organized PS-b-PBD film is first ozonated, then etched by reactive ion etching to produce a silicon nitride film with a pattern of holes (see for example Park, et al., Science, 276, 1401 (1997)). In another embodiment, the BCP is PS-b-PBD, the substrate is silicon nitride, and following exposure to a suitable energy source, the organized PS-b-PBD film is first stained with an osmium dye, then etched by reactive ion etching to produce a pattern on the silicon nitride.

In a further embodiment, the pattern of the BCP film is transferred into an alternate material by treatment with nanoparticles either during or following the exposure to a suitable energy source (see for example, Kashem et al., Macromolecules, 42, 6202 (2009)). In a further embodiment, the BCP is PS-b-PMMA and an amount of iron oxide nanoparticles are mixed with the film during exposure to a suitable energy source. The nanoparticles selectively bind to the PMMA block, and assume the organization of the PMMA component within the block copolymer film.

In another embodiment, a metal-bound BCP substrate is subjected to galvanic displacement, in which metal nanoparticles are directly formed during the galvanic displacement process. In this embodiment, the block copolymer is then removed by dissolving the polymer on the substrate using an organic solvent, such as toluene or THF.

The present disclosure is also directed to a substrate comprising an organized block copolymer comprising nanodot arrays or nanolines produced in accordance with the method of the present disclosure.

The following non-limiting examples are illustrative of the present disclosure:

### EXAMPLES

### Reagents and Materials

Silicon wafers were purchased from Addison Engineering. Asymmetric diblock copolymers were purchased from Polymer Source Inc., and Na₂PtCl₄ was obtained from Strem Chemicals. Toluene and THF were HPLC grade, purchased from Sigma-Aldrich. Hydrogen peroxide (Fisher, 30%), ammonium hydroxide (J. T. Bakers, 30%), ethanol (Fisher, 99.8%), acetone (Fisher, 99.6%) and hydrochloric acid (J. T. Bakers, 36.5%) were used as received. High purity water (18 MΩ·cm, Barnstead Nanopure water) was used throughout the experiment, and plasma treatments were performed in a PlasmaLab μEtch reactive ion etch system.

### Example 1

### Generation of an Organized Array of Parallel PS-PVP Nanolines

A prime-grade 4-inch diameter Si (100) wafer (ρ=0.002-0.005 Ω·cm) was cut into approximately 0.9 by 0.9 cm pieces. These silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

The diblock copolymer solution was prepared in toluene. Polystyrene(PS)-(23.6 k)-b-poly-2-vinylpyridine(P2VP)-(10.4 k) (the number after each block denote the molecular weight of that block in g/mol) was weighed and dissolved in toluene at room temperature by stirring overnight to make a ˜1% w/w solution of polymer micelles. A 16-μL volume of the block copolymer sample solution was then dropped onto the cleaned Si wafer and spin-coated for 40 seconds at a rate of 4000 rpm under an argon environment to form a thin film.

A Biotage Initiator 2.5 system was used as the microwave source to anneal the polymer film: the polymer-coated silicon wafers were first cut into 0.45 cm×0.9 cm shards in order to fit into the 2-5 mL microwave-safe sample tube. Inside the sample tube, a microwave-safe glass support was used to hold the silicon shard above a small volume of tetrahydrofuran. The tube was then sealed and placed inside the reaction chamber. The tube was then irradiated with microwaves for 3 minutes at an average power of 110 W. The microwave-induced heating transformed the block copolymer semi-random micelle pattern into parallel nanolines in which cylindrical domains of P2VP are surrounded by a PS matrix.

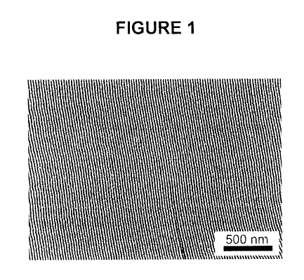

In order to improve visualization by scanning electron microscopy (SEM), the microwave-annealed PS-P2VP pattern was also metallized. To accomplish this, the microwave-annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. A scanning electron micrograph is shown in FIG. 1.

### Example 2

### Generation of Organized Arrays of Parallel PS-PVP Nanolines at Different Temperatures and in the Presence of Toluene

A prime-grade 4-inch diameter Si (100) wafer (ρ=0.002-0.005 Ω·cm) was cut into approximately 0.9 by 0.9 cm pieces. These silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

The diblock copolymer solution was prepared in toluene. Polystyrene(PS)-(23.6 k)-b-poly-2-vinylpyridine(P2VP)-(10.4 k) was weighed and dissolved in toluene at room temperature by stirring overnight to make a ˜1% w/w solution of polymer micelles. Volumes of 16 μL of the block copolymer sample solution were then dropped onto the cleaned Si wafer pieces which were then spin-coated for 40 seconds at a rate of 4000 rpm under an argon environment to form thin films.

A Biotage Initiator 2.5 system was used as the microwave source to anneal the polymer films: the polymer-coated silicon wafers were first cut into ˜0.45 cm×0.9 cm shards in order to fit into the 2-5 mL microwave-safe sample tubes. Inside the sample tubes, a microwave-safe glass support was used to hold the silicon shards above a small volume of toluene. The tubes were then sealed and placed inside the reaction chamber. The tubes were then irradiated with microwaves for 5 minutes, but each tube was irradiated at a different average microwave power. In each of these experiments, a target tube temperature was chosen, and microwave power was automatically and continuously adjusted by the Biotage Initiator to achieve and maintain the selected target tube temperature. Eight different target temperatures were used: 60° C., 80° C., 100° C., 115° C., 130° C., 145° C., 160° C. and 175° C. The microwave-induced heating transformed the block copolymer semi-random micelle pattern into a parallel nanoline pattern in which cylindrical domains of P2VP are surrounded by a PS matrix. Within the temperature range used in this experiment, greater temperatures led to better organization of the resulting nanoline patterns.

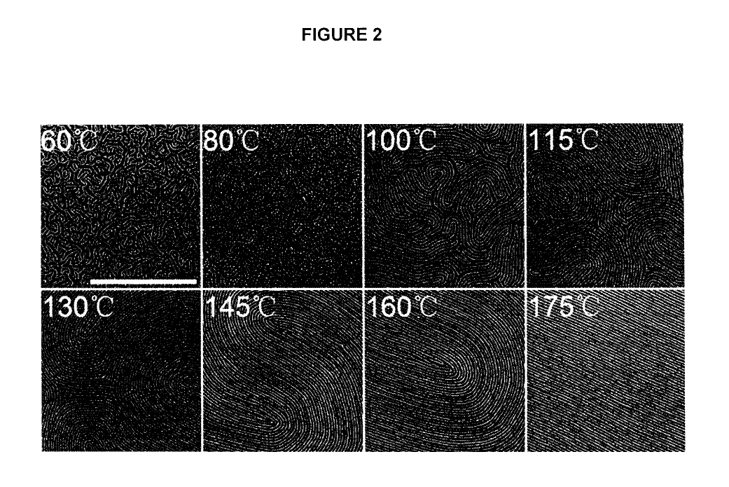

In order to improve visualization by SEM, the microwave-annealed PS-P2VP patterns were also metallized. To accomplish this, the microwave-annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. Scanning electron micrographs of patterns produced in each of the eight experiments are shown in FIG. 2. In this FIG. 2, the scale bar represents 1 μm, the scale is the same for each panel, and the target temperature for each experiment is noted on the corresponding image.

### Example 3

### Generation of Organized Arrays of Parallel PS-PVP Nanolines at Different Temperatures and in the Presence of THF

A prime-grade 4-inch diameter Si (100) wafer (ρ=0.002-0.005 Ω·cm) was cut into approximately 0.9 by 0.9 cm pieces. These silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

The diblock copolymer solution was prepared in toluene. Polystyrene(PS)-(23.6 k)-b-poly-2-vinylpyridine(P2VP)-(10.4 k) was weighed and dissolved in toluene at room temperature by stirring overnight to make a ˜1% w/w solution of polymer micelles. Volumes of 16 μL of the block copolymer sample solution were then dropped onto the cleaned Si wafer pieces which were then spin-coated for 40 seconds at a rate of 4000 rpm under an argon environment to form thin films.

A Biotage Initiator 2.5 system was used as the microwave source to anneal the polymer films: the polymer-coated silicon wafers were first cut into ˜0.45 cm×0.9 cm shards in order to fit into the 2-5 mL microwave-safe sample tubes. Inside the sample tubes, a microwave-safe glass support was used to hold the silicon shards above a small volume of tetrahydrofuran.

The tubes were then sealed and placed inside the reaction chamber. The tubes were then irradiated with microwaves for 5 minutes, but each tube was irradiated at a different average microwave power. In each of these experiments, a target tube temperature was chosen, and microwave power was automatically and continuously adjusted by the Biotage Initiator to achieve and maintain the selected target tube temperature. Eight different target temperatures were used: 60° C., 70° C., 80° C., 90° C., 100° C., 110° C., 120° C. and 130° C. The microwave-induced heating transformed the block copolymer semi-random micelle pattern into a parallel nanoline pattern in which cylindrical domains of P2VP are surrounded by a PS matrix. Within the temperature range used in this experiment, greater temperatures led to better organization of the resulting nanoline patterns.

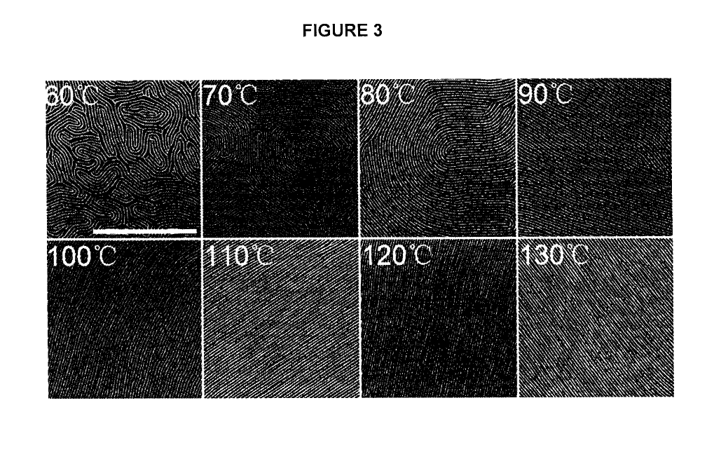

In order to improve visualization by SEM, the microwave-annealed PS-P2VP patterns were also metallized. To accomplish this, the microwave-annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. Scanning electron micrographs of patterns produced in each of the eight experiments are shown in FIG. 3. In this FIG. 3, the scale bar represents 1 μm, the scale is the same for each panel, and the target temperature for each experiment is noted on the corresponding image.

### Example 4

### Generation of an Organized Array of Parallel PS-PVP Nanolines from Substrates of Different Resistivity

Prime-grade 4-inch diameter Si (100) wafers were cut into approximately 0.9 by 0.9 cm pieces. These pieces were prepared from four different wafers in this example, and each of these wafers had a different resistivity: 1-5 Ω·cm, 0.1-0.08 Ω·cm, 0.01-0.02 Ω·cm, 0.002-0.005 Ω·cm. The silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

The diblock copolymer solution was prepared in toluene. Polystyrene(PS)-(32.5 k)-b-poly-2-vinylpyridine(P2VP)-(12.0 k) was weighed and dissolved in toluene at room temperature by stirring overnight to make a ˜1% w/w solution of polymer micelles. Volumes of 16 μL of the block copolymer sample solution were then dropped onto the cleaned Si wafer pieces which were then spin-coated for 40 seconds at a rate of 4000 rpm under an argon environment to form thin films.

A Biotage Initiator 2.5 system was used as the microwave source to anneal the polymer films: the polymer-coated silicon wafers were first cut into ˜0.45 cm×0.9 cm shards in order to fit into the 2-5 mL microwave-safe sample tubes. Inside the sample tubes, a microwave-safe glass support was used to hold the silicon shards above a small volume of tetrahydrofuran. The tubes were then sealed and placed inside the reaction chamber. The tubes were then irradiated with microwaves for 5 minutes at a target temperature of 130° C. In each of these experiments, the microwave power was automatically and continuously adjusted by the Biotage Initiator to achieve and maintain the 130° C. target temperature. The microwave-induced heating transformed the block copolymer semi-random micelle pattern into a parallel nanoline pattern in which cylindrical domains of P2VP are surrounded by a PS matrix. It was found that substrates with lower resistivity led to better ordered nanoline patterns in this set of experiments.

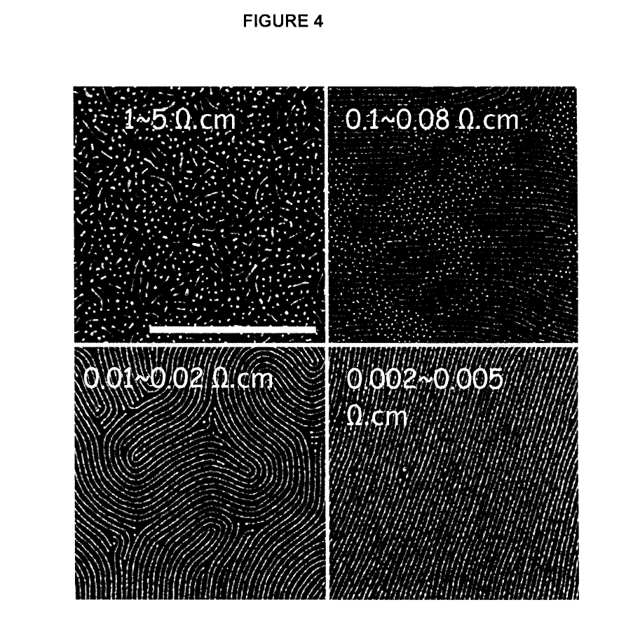

In order to improve visualization by SEM, the microwave-annealed PS-P2VP patterns were also metallized. To accomplish this, the microwave-annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. Scanning electron micrographs of patterns produced in each of the four experiments are shown in FIG. 4. In this FIG. 4, the scale bar represents 1 μm, the scale is the same for each panel, and the substrate resistivity for each experiment is noted on the corresponding image.

### Example 5

### Generation of Organized Arrays of Variably-Spaced PS-PVP Nanolines

A prime-grade 4-inch diameter Si (100) wafer (ρ=0.002-0.005 Ω·cm) was cut into approximately 0.9 by 0.9 cm pieces. These silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

Various diblock copolymer solutions were prepared in toluene. PS(32.5 k)-b-P2VP(12 k), PS(44 k)-b-P2VP(18.5 k), PS(50 k)-b-P2VP(16.5 k) were weighed and dissolved in toluene at room temperature by stirring overnight to make a ˜1% w/w solutions of polymer micelles. Volumes of 16 μL of each block copolymer solution were then dropped onto separate cleaned Si wafers which were then spin-coated for 40 seconds at the rate of 4000 rpm under an argon environment to form a thin film.

A Biotage Initiator 2.5 system was used as the microwave source to anneal the polymer film: the polymer coated silicon wafers were first cut into 0.45 cm×0.9 cm shards in order to fit into the 2-5 mL microwave-safe sample tube. Inside the sample tubes, microwave-safe glass supports were used to hold the silicon shards above small volumes of tetrahydrofuran. The tubes were then sealed and placed inside the reaction chamber. These tubes, carrying the BCP films of differing block lengths, were then each irradiated with microwaves for 3 minutes with an average power of 110 W.

In order to improve visualization by SEM, the microwave-annealed PS-P2VP patterns were also metallized. To accomplish this, the microwave annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes.

### Discussion

The microwave-induced heating transformed the semi-random

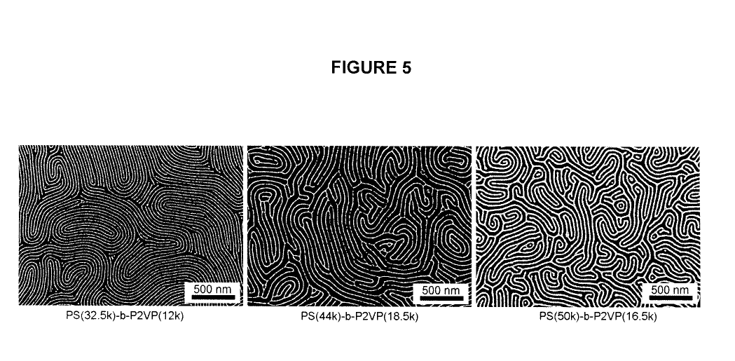

BCP domains into an organized arrangement of parallel cylindrical domains of P2VP surrounded by a PS matrix. The width and spacing of the parallel domains were controlled based on the block lengths of the BCP. Scanning electron micrographs are shown in FIG. 5.

### Example 6

### Generation of an Organized Array of PS-PMMA Nanolines

A prime-grade 4-inch diameter Si (100) wafer (ρ=0.002-0.005 Ω·cm) was cut into approximately 0.9 by 0.9 cm pieces. These silicon pieces were degreased in an ultrasonic bath of methanol, rinsed in acetone and ethanol, and then dried by a stream of nitrogen gas. For cleaning, standard RCA procedures were used. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

The diblock copolymer solution was prepared in toluene. PS(52 k)-b-PMMA(52 k) was weighed and dissolved in toluene at room temperature by stirring overnight to make a ˜1% w/w solution of polymer micelles. A 16-μL volume of the block copolymer sample solution was then dropped onto the cleaned Si wafer and spin-coated for 40 seconds at the rate of 4000 rpm under an argon environment to form a thin film.

A Biotage Initiator 2.5 system was used as the microwave source to anneal the polymer film: the polymer coated silicon wafers were first cut into 0.45 cm×0.9 cm shards in order to fit into the 2-5 mL microwave-safe sample tube. Inside the sample tube, a microwave-safe glass support was used to hold the silicon shard above a small volume of tetrahydrofuran. The tube was then sealed and placed inside the reaction chamber. The tube was then irradiated with microwaves for 3 minutes at an average power of 110 W. The microwave-induced heating transformed the block copolymer semi-random micelle pattern into a fingerprint pattern which has cylindrical domains of PMMA surrounded by a PS matrix.

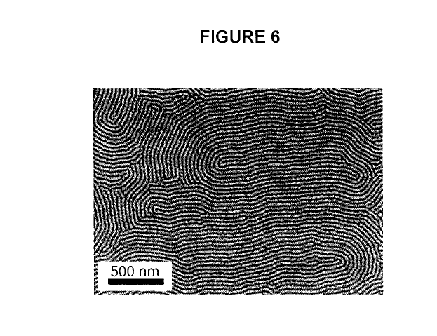

In order to improve visualization by SEM, the microwave-annealed PS-PMMA pattern was treated by oxygen plasma at 0.12 torr for 30 seconds. The PS blocks are etched more quickly than the PMMA blocks. A scanning electron micrograph is shown in FIG. 6.

### Example 7

### Directed Generation of Organized PS-PVP Nanolines Using Graphoepitaxy

Wall-like features for graphoepitaxy were formed using electron beam lithography. First, diced 9×9 mm pieces of a silicon wafer were cleaned in piranha (3:1 mixture of H₂SO₄ and H₂O₂) for 15 minutes. The clean and dried Si pieces were then baked at 150° C. for 15 minutes to drive off any remaining water from the surface. A 1% solution of hydrogen silsesquioxane (HSQ) in methyl isobutyl ketone (MIBK) solvent was then spun onto each square with a spread speed of 1000 rpm for 10s, and a spin speed at 3000 rpm for 30s, followed by a bake at 100° C. for 15 minutes. The samples were then loaded into a RAITH 150-2 system, which was used to write patterns in the HSQ. Patterns of circles, lines, ellipses, stars, and letters were written in the HSQ film forming SiO₂ in all areas exposed to the electron beam. All remaining (i.e., unexposed) HSQ was then removed by immersing the substrate in a 25% solution of tetramethylammonium hydroxide (TMAH) for 30 s, leaving behind only raised SiO₂ features.

The diblock copolymer solution was prepared in toluene. PS(32.5 k)-b-P2VP(12 k) was weighed and dissolved in toluene at room temperature by stirring overnight to make a ˜1% w/w solution of polymer micelles. A 16-μL volume of the block copolymer solution was then dropped onto the cleaned and SiO₂-patterned Si wafer described above. This substrate was then spin-coated for 40 seconds at the rate of 4000 rpm under an argon environment to form a thin film.

A Biotage Initiator 2.5 system was used as the microwave source to anneal the polymer film: the polymer-coated silicon wafers were first cut into 0.45 cm×0.9 cm shards in order to fit into the 2-5 mL microwave-safe sample tube. Inside the sample tube, a microwave-safe glass support was used to hold the silicon shard above a small volume of tetrahydrofuran. The tube was then sealed and placed inside the reaction chamber. The tube was then irradiated with microwaves for 3 minutes at an average power of 110 W.

The microwave-induced heating transformed the block copolymer semi-random micelle pattern into a pattern of concentric circles which has cylindrical domains of P2VP surrounded by a PS matrix. In this case, the pre-written SiO₂ features guided the organization of the BCP domains.

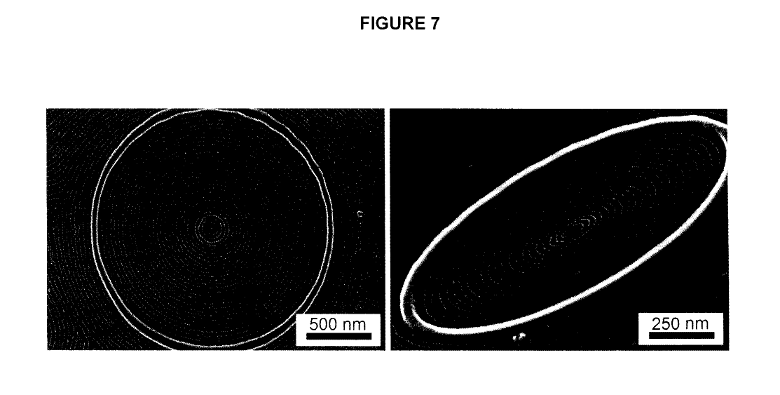

In order to improve visualization by SEM, the microwave-annealed PS-P2VP pattern was metallized. To accomplish this, the microwave annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. A scanning electron micrograph is shown in FIG. 7.

### Example 8

### Process for Microwave Irradiation of BCP-Coated Substrate

The process of the present disclosure can be performed using a conventional microwave oven. The desired solvent is first pipetted into a Teflon holder. The unannealed spin coated BCP sample is then placed inside the holder on a platform such that it is not immersed in the solvent. The lid on the holder is quickly placed on the holder. The holder is then placed in the microwave in which the rotary tray has been removed and the holder is placed in the centre of the microwave oven. The microwave is then powered on to induce sample heating and accelerate the organization of the block copolymer. The sample is then removed from the microwave.

### Example 9

### Generation of Organized Arrays of Variably-Spaced PS-PVP Nanolines

A prime-grade 4-inch diameter Si (100) wafer (ρ=1.5 Ω·cm) was cut into approximately 0.9 by 0.9 cm pieces. These silicon pieces were degreased in an ultrasonic bath of methanol, rinsed in acetone and ethanol, and then dried by a stream of nitrogen gas. Standard RCA procedures were used for cleaning. First, the silicon wafers were immersed in a hot solution of NH₄OH, H₂O₂ and high purity water in a ratio of 1:1:5 at 85° C. for 20 min. The wafers were then rinsed with water and immersed in another hot solution of HCl, H₂O₂ and high purity water in a ratio of 1:1:5 at 85° C. for 20 min. The wafers were then rinsed with water and dried in a nitrogen gas flow.

A 0.9% PS(23.6 k)-b-P2VP(10.4 k) solution was prepared in toluene. A 16-μL volume of the block copolymer solution was then dropped onto a cleaned Si wafer which was then spin-coated for 15 seconds at the rate of 4200 rpm under an argon environment to form a thin film.

A Panasonic® N,N-SD377S conventional microwave oven was used as the microwave source to anneal the polymer film: the polymer coated silicon wafers were first cut into 0.9 cm×0.9 cm shards and placed inside a Teflon holder. Inside the Teflon holder, microwave-safe glass supports were used to hold the silicon shards above small volumes of tetrahydrofuran. The tubes were then sealed and placed inside the reaction chamber. These tubes, carrying the BCP film, were then irradiated in the microwave for 60 or 90 seconds at full power (setting of 10) with an average power of 800 W.

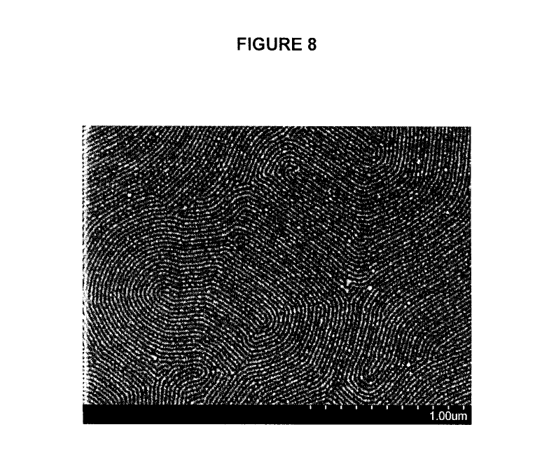

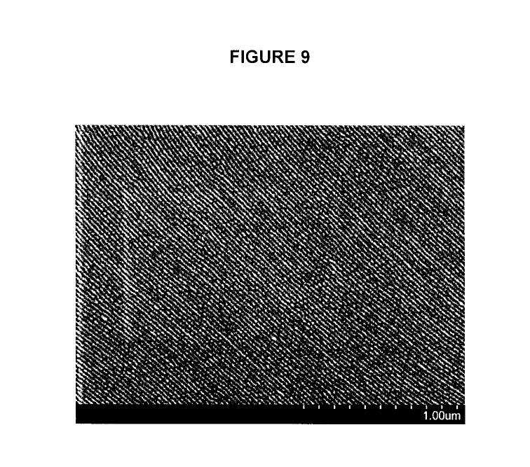

In order to improve visualization by SEM, the microwave-annealed PS-P2VP patterns were also metallized. To accomplish this, the microwave annealed wafers were immersed in a Na₂PtCl₄ solution (20 mM) with HCl (3%) for 3 hours in a glass beaker. After metal deposition, the samples were rinsed thoroughly with water and dried by a stream of nitrogen gas. Following metal loading, the bound ions were reduced and polymer removed by performing an oxygen plasma treatment at 0.12 torr for 8 minutes. Scanning electron micrographs of samples irradiated for 60 s and 90 s are shown in FIGS. 8 and 9, respectively.

### DISCUSSION

As shown in FIGS. 8 and 9, conventional microwaves are useful as the source of microwave energy and bring about high speed block copolymer organization. Accordingly, high degrees of order are obtained in a process that lasts between 60 s to 90 s, with a longer irradiation time leading to a higher degree of order.

We claim:

1. A method for organizing a block copolymer (BCP), comprising:
(i) contacting a substrate with the BCP, wherein the BCP has at least a first block and a second block; and
(ii) exposing the BCP-coated substrate to a suitable energy source under conditions sufficient to induce substrate heating and arrange at least the first and second blocks into organized domains.

2. The method according to claim 1, wherein the suitable energy source comprises an electromagnetic energy source, an electrical energy source, or a magnetic energy source.

3. The method according to claim 2, wherein the electromagnetic energy comprises microwave radiation energy or infrared energy.

4.-6. (canceled)

7. The method according to claim 1, wherein the domains of the block copolymer are organized into nanostructures.

8. The method according to claim 7, wherein the blocks of the block copolymer have a length and the length determines the size of the features of the nanostructures.

9. The method according to claim 7, wherein the nanostructures comprise nanodots or cylinders.

10. The method according to claim 9, wherein the nanostructures comprise parallel cylinders oriented along the substrate.

11.-12. (canceled)

13. The method according to claim 1, wherein the block copolymer is a diblock copolymer.

14. The method according to claim 13, wherein the diblock copolymer is a polymer of the formula (I):
A-B (I)
wherein A is a repeating polymeric monomer unit of the formula (II): 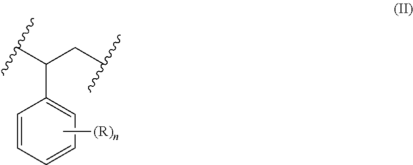
wherein each R is independently or simultaneously selected from H, halo, (C₁-C₆)-alkyl, —O—(C₁-C₆)-alkyl or fluoro-substituted-(C₁-C₆)-alkyl, and
n is 1, 2, 3, 4 or 5; and
B is a repeating polymeric monomer unit of the formula (III): 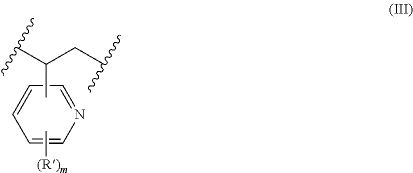
wherein each R′ is independently or simultaneously selected from H, halo, (C₁-C₆)-alkyl, —O—(C₁-C₆)-alkyl or fluoro-substituted-(C₁-C₆)-alkyl, and
m is 1, 2, 3 or 4.

15. The method according to claim 14, wherein A is

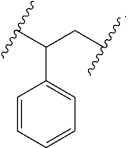

16. (canceled)

17. The method according to claim 16, wherein B is

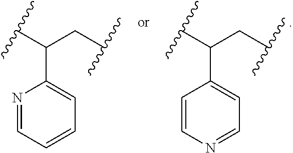

18. The method according to claim 13, wherein one block of the diblock copolymer comprises polymethylmethacrylate (PMMA) or polydimethylsiloxane (PDMS).

19. (canceled)

20. The method according to claim 1, wherein the substrate comprises silicon, GaAs, Ge, a semiconductor, a metal, a plastic film, a transparent conducting oxide, or topographically-patterned or chemically-patterned derivatives thereof.

21. (canceled)

22. The method according to claim 20, wherein the substrate has an electrical resistivity between 1×10⁻⁶ Ω·cm and 1×10⁵ Ω·cm.

23. (canceled)

24. The method according to claim 1, wherein a non-substrate energy absorber is used to transfer energy to the substrate.

25.-27. (canceled)

28. The method according to claim 1, wherein the block copolymer is provided with conditions sufficient to induce substrate heating while in the presence of a solvent.

29. (canceled)

30. The method according to claim 3, wherein the BCP-coated substrate is exposed to microwave radiation for between 1 second and 24 hours.

31.-33. (canceled)

34. The method according to claim 3, wherein the BCP-coated substrate is exposed to microwave radiation for less than 90 seconds.

35.-36. (canceled)

37. The method according to claim 1, wherein the method further comprises contacting the organized BCP-coated substrate with a metal salt whereby metal ions bind to the domains of the block copolymer.

38. A substrate with nanostructures or nanoscale features prepared in accordance with claim 1.
